(19) United States
(12) Patent Application Publication
(10) Pub. No.: US 2015/0307998 A1
(43) Pub. Date: Oct. 29, 2015

(54) MULTILAYER THIN FILM FOR CUTTING TOOL AND CUTTING TOOL INCLUDING THE SAME

(71) Applicant: KORLOY INC., Seoul (KR)

(72) Inventors: Seung-Su AHN, Cheongju-si, Chungcheongbuk-do (KR); Je-Hun PARK, Cheongju-si, Chungcheongbuk-do (KR); Jae-Hoon KANG, Cheongju-si, Chungcheongbuk-do (KR); Sung-Gu LEE, Cheongju-si, Chungcheongbuk-do (KR); Sun-Yong AHN, Cheongju-si, Chungcheongbuk-do (KR)

(73) Assignee: KORLOY INC., Seoul (KR)

(21) Appl. No.: 14/649,551

(22) PCT Filed: Nov. 14, 2013
(86) PCT No.: PCT/KR2013/010334

§ 371 Date: Jun. 4, 2015

(30) Foreign Application Priority Data
Dec. 27, 2012 (KR) 10-2012-0155125

(51) Int. Cl. C23C 28/04; C23C 28/00; C23C 14/06

(52) U.S. Cl. CPC C23C 28/044; C23C 14/0641; C23C 28/042; C23C 28/44

(57) ABSTRACT

Provided is a multilayer thin film for a cutting tool, in which micro-scale thin films having a thickness of a few nanometers to tens of nanometers are alternately stacked, having less quality variations and being capable of realizing excellent wear resistance. The multilayer thin film according to the present disclosure is a multilayer thin film for a cutting tool, in which unit thin films which are respectively formed of thin layers A, B, C, and D are stacked more than once, wherein elastic moduluses k of the thin layers satisfy relationships of k_{A}>k_{B}, k_{D}>k_{C} or k_{C}>k_{B}, k_{D}>k_{A}, lattice parameters L of the thin layers satisfy relationships of L_{A}, L_{C}>L_{B}, L_{D} or L_{B}, L_{D}>L_{A}, L_{C}, and a difference between maximum and minimum values of the lattice parameter L is 20% or less.

### TECHNICAL FIELD

The present disclosure relates to a multilayer thin film for a cutting tool, and more particularly, to a multilayer thin film for a cutting tool, in which a superlattice thin film having a thickness of a few nanometers to tens of nanometers is stacked in the form of A-B-C-D or A-B-C-B, having less quality variations and being capable of realizing excellent wear resistance.

### BACKGROUND ART

Since the late 1980s, a variety of TiN-based multilayer film systems have been proposed in order to develop materials for a cutting tool having high hardness.

As an example, a multilayer film formed by alternately and repeatedly stacking TiN or VN into a few nanometer thickness forms the so-called superlattice having a single lattice parameter with coherent interfaces between layers despite differences in lattice parameters in single layers each, and this coating may realize twice or more high hardness compared with general hardness of each single layer, so that there have been various attempts for applying this phenomenon to thin films for cutting tools.

Examples of strengthening mechanisms used for these superlattice coatings include a Koehler's model, a Hall-Petch relationship, and a Coherency strain model, and these strengthening mechanisms relate to an increase in hardness through a difference between lattice parameters of A and B, a difference between elastic moduluses of A and B, and control of stacking periods of A and B, upon alternate deposition of A and B materials.

In general, it is difficult to apply two or more mechanisms of the strengthening mechanisms through alternate stacking of two materials. Particularly, it is difficult to manufacture a multilayer thin film having excellent wear resistance with a uniform quality under the mass production condition having severe deviations in a stacking period of the multilayer thin film between lots as well as in a lot.

Accordingly, as illustrated in FIG. 1, in the formation of a multilayer thin film through alternate stacking of two or more materials, it was conventionally common to perform the stacking in such a way that an elastic period and a lattice period coincide with each other, as disclosed in U.S. Pat. No. 5,700,551. However, in this case, it is difficult to simultaneously utilize the aforesaid various strengthening mechanisms, so that there has been a limitation in improving the wear resistance of the multilayer film.

### DISCLOSURE OF THE INVENTION

### Technical Problem

The purpose of the present disclosure is, in the formation of a multilayer thin film formed of a superlattice, to provide a multilayer thin film for a cutting tool, which has improved wear resistance compared with conventional superlattice coatings, and a cutting tool coated with the multilayer thin film, by adjusting a lattice period and an elastic period of the multilayer thin film so that two or more thin film strengthening mechanisms act on the multilayer thin film.

### Technical Solution

In order to solve the above technical problem, the present disclosure provides a multilayer thin film for a cutting tool, in which unit thin films which are respectively formed of thin layers A, B, C, and D are stacked more than once, wherein elastic moduluses k of the thin layers satisfy relationships of k_{A}>k_{B}, k_{D}>k_{C} or k_{C}>k_{B}, k_{D}>k_{A}, lattice parameters L of the thin layers satisfy relationships of L_{A}, L_{C}>L_{B}, L_{D} or L_{B}, L_{D}>L_{A}, L_{C}, and a difference between maximum and minimum values of the lattice parameter L is 20% or less.

In the multilayer thin film according to the present disclosure, an average lattice period λ_{L} of the multilayer thin film may be one half of an average elastic period λₖ thereof.

In the multilayer thin film according to the present disclosure, the unit thin film may have a thickness of 4 to 50 nm, and more preferably 10 to 30 nm.

In the multilayer thin film according to the present disclosure, the thin layers B and D may be formed of the same material.

Furthermore, the present disclosure provides a cutting tool of which the surface is coated with the multilayer thin film.

### Advantageous Effects

According to the present disclosure, upon forming a superlattice multilayer thin film in such a way that four or more unit thin film layers are laminated into a film and then the laminated film is repeatedly stacked into two or more layers, changes in stacking periods of the elastic modulus and the lattice parameter according to the stacking period of the unit thin film are controlled as in FIG. 2, so that two or more strengthening mechanisms act on the multilayer thin film. Accordingly, there may be provided a multilayer thin film for a cutting tool, having less quality variations and improved wear resistance compared with a multilayer thin film on which a single strengthening mechanism acts.

### BRIEF DESCRIPTION OF THE DRAWINGS

FIG. 1 shows the relationship between an elastic period and a lattice period in a conventional superlattice multilayer thin film.

FIG. 2 shows the relationship between an elastic period and a lattice period in a superlattice multilayer thin film according to the present disclosure.

FIG. 3 is a graph showing changes in a lattice parameter according to aluminum content in a (Ti₁₋ₓAlₓ)N based thin film.

FIG. 4 is photographs showing cutting performance test results of a multilayer thin film according to Example 1 of the present disclosure and a multilayer thin film according to Comparative Example.

FIG. 5 is photographs showing cutting performance test results of a multilayer thin film according to Example 2 of the present disclosure and a multilayer thin film according to Comparative Example.

### MODE FOR CARRYING OUT THE INVENTION

Hereinafter, the present disclosure will be described in detail based on preferred embodiments thereof, but the inventive concept is not limited to embodiments below.

The present inventors found that when an elastic period and a lattice period are adjusted differently with each other in the stacking of a unit thin film instead of making the two periods coincide with each other, two or more strengthening mechanisms (i.e., the Koehler's model mechanism and the Hall-Petch relationship mechanism) may effectively act, particularly on a laminated superlattice thin film, and wear resistance of the multilayer thin film is thus improved and quality variations are also reduced in a mass production compared with a multilayer thin film on which a single strengthening mechanism mainly acts, and finally completed the present invention.

The multilayer thin film according to the present disclosure is a multilayer thin film for a cutting tool, in which a thin film formed by sequentially stacking unit thin films which are respectively formed of thin layers A, B, C, and D is repeatedly stacked into two or more layers, wherein elastic moduluses k of the unit thin films satisfy relationships of k_{A}>k_{B}, k_{D}>k_{C} or k_{C}>k_{B}, k_{D}>k_{A}, lattice parameters L of the unit thin films satisfy relationships of L_{A}, L_{C}>L_{B}, L_{D} or L_{B}, L_{D}>L_{A}, L_{C}, and a difference between maximum and minimum values of the lattice parameter L is 20% or less.

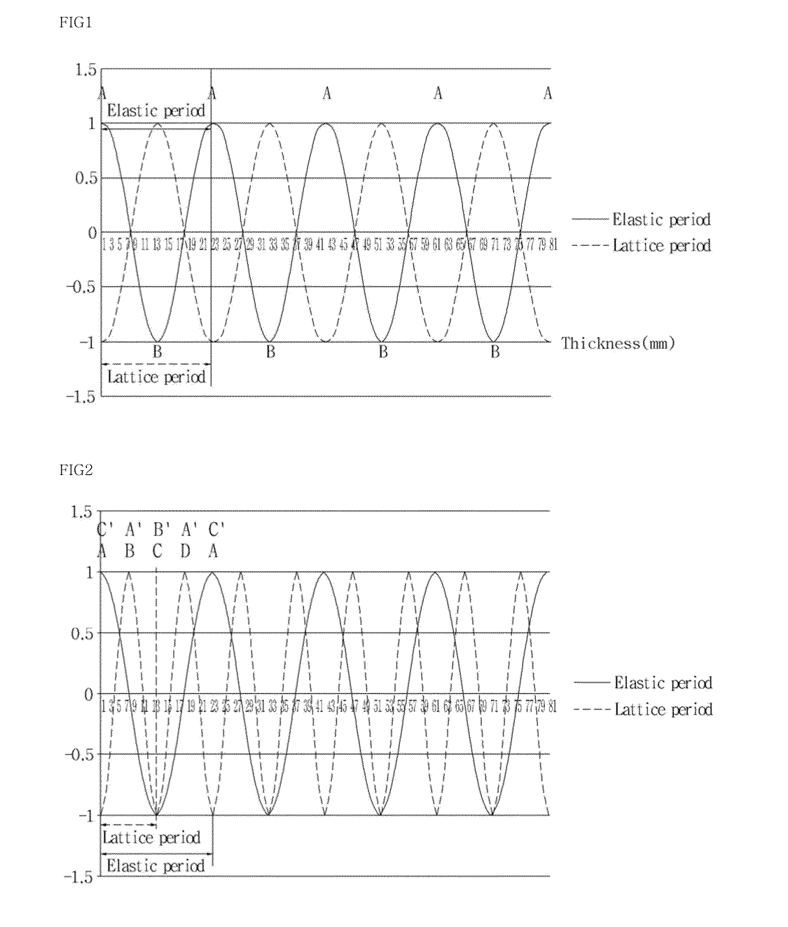

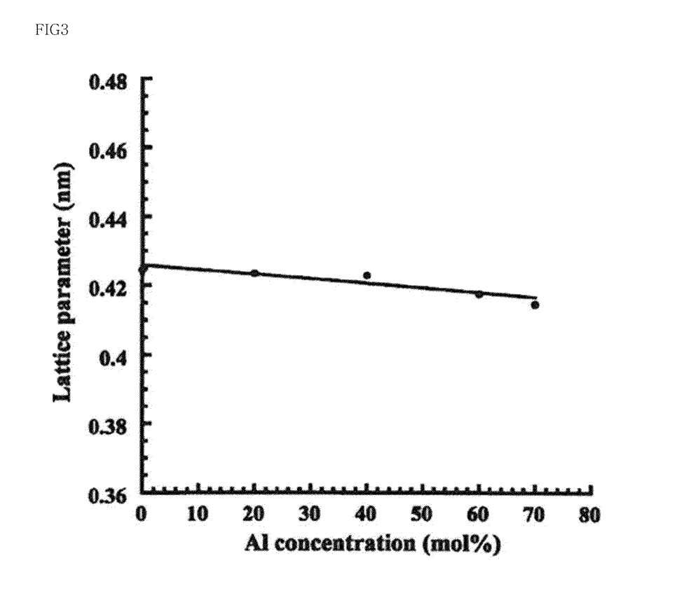

FIG. 2 shows an example of the relationship between an elastic period and a lattice period in a superlattice multilayer thin film according to the present disclosure. As shown in FIG. 2, it can be seen that the superlattice multilayer thin film is unlike in FIG. 1 in that the elastic period (blue) is about twice as large as the lattice period (red), and the elastic period and the lattice period thus do not coincide with each other.

In the Koehler model relating to the elastic modulus, it is described that the strengthening effect is generated when thicknesses of thin films A and B become small enough to be less than or equal to 20 to 30 nm corresponding to a thickness of about 100 atomic layers, which is a critical thickness at which it is difficult to create dislocation. The inventive concept is that the elastic period and the lattice parameter period are adjusted to be in discord with each other so that the two strengthening effects may be generated.

Also, when the difference between maximum and minimum values of the lattice parameter L is greater than 20%, it is difficult to form the superlattice. Therefore, it is preferable to adjust the lattice parameter so that the difference is generated in the range of 20% or less if possible.

The multilayer thin film according to the present disclosure is intended that the unit thin films are formed of four layers, and stacking of each unit thin film may be formed in the order of A-B-C-D or A-B-C-B. That is, second and fourth layers may be formed of different materials, or the same material.

Furthermore, a difference between an average elastic period and an average lattice parameter period falls within the scope of the present disclosure, and preferably, the average elastic period may be twice as large as the average lattice period.

### EXAMPLE

Prior to the formation of a superlattice multilayer thin film in which a thin film formed of four unit thin films is repeatedly stacked into two or more layers, a monolayer thin film was deposited to measure the elastic modulus of each unit thin film in order to confirm the elastic modulus of each unit thin film. The results are shown in Table 1.

An arc ion plating which is physical vapor deposition (PVD) was used for the deposition of the unit thin film. Initial vacuum pressure was reduced to 8.5×10⁻⁵ Torr or less, N₂ was then injected as a reaction gas, and deposition was conducted under the condition of a reaction gas pressure of 40 mTorr or less (preferably 10 to 35 mTorr), a temperature of 400 to 600° C., and a substrate bias voltage of −30 to −150 V.

TABLE 1

| | Target composition | Elastic modulus k |
|---|---|---|
| Thin film | (at %) | (GPa) |
| TiN | Ti = 99.9 | 416 |
| TiAlN | Ti:Al = 75:25 | 422 |
| TiAlN | Ti:Al = 50:50 | 430 |
| AlTiN | Ti:Al = 33:67 | 398 |
| CrN | Cr = 99.9 | 475 |
| CrAlN | Cr:Al = 50:50 | 367 |
| AlCrN | Cr:Al = 30:70 | 403 |
| AlCrSiN | Cr:Al:Si = 30:65:5 | 338 |

The lattice parameter of each unit thin film forming the multilayer thin film may be obtained using an XRD analysis following the formation of the monolayer thin film, but in the embodiment of the present disclosure, the lattice parameter of each unit thin film was determined using atomic, ionic, and covalent radii obtained from existing experiments and theories. Specifically, the lattice parameter was calculated by quantitatively applying the covalent radius to B1 HCP structure according to the atomic ratio

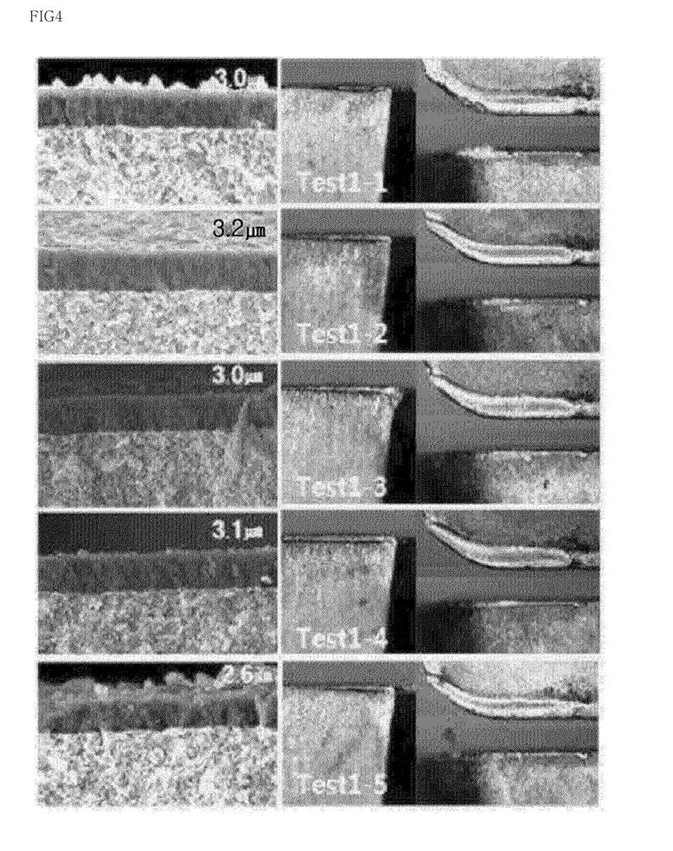

As shown in FIG. 3, in the case of the (Ti₁₋ₓAlₓ)N based thin film, the lattice parameter tends to decrease approximately linearly as aluminum content increases, and the lattice parameter of the (Ti₁₋ₓAlₓ)N based thin film may thus be obtained by Equation 1 below.

Lattice parameter: a=4.24 Å−0.125xÅ (x is a molar ratio of aluminum) [Equation 1]

### Example 1

In Example 1 of the present disclosure, the case of forming a TiAlN-based multilayer thin film by the method according to the present disclosure was compared with the case of forming a TiAlN-based multilayer thin film by a conventional method.

Stacking structures and compositions of the multilayer thin film were set as shown in Table 2 below. A thin film formed of four unit thin film layers was repeatedly stacked a total of 180 times so that the average lattice period was 5 to 10 nm and the elastic period was 10 to 20 nm, and a multilayer thin film having a final film thickness of 2.6 to 3.2 μm was thus obtained. In this case, A30 (Model No. SPKN1504EDSR), which is a P30 material available from Korloy, was used as a substrate on which the multilayer thin film was deposited.

TABLE 2

| Thin | | | | | | |
|---|---|---|---|---|---|---|
| film | Target | A | B | C | D | Remark |
| 1-1 | composition | Ti:Al = | Ti:Al = | Ti:Al = | Ti:Al = | Example |
| | | 50:50 | 75:25 | 33:67 | 75:25 | |
| | Lattice | 423 | 442.5 | 409.7 | 442.5 | |
| | parameter | | | | | |
| | Elastic | 430 | 422 | 398 | 422 | |
| | modulus | | | | | |
| 1-2 | composition | Ti:Al = | Ti:Al = | Ti:Al = | Ti:Al = | Comparative |
| | | 33:67 | 33:67 | 75:25 | 75:25 | Example |
| | Lattice | 409.7 | 409.7 | 442.5 | 442.5 | |
| | parameter | | | | | |
| | Elastic | 398 | 398 | 422 | 422 | |
| | modulus | | | | | |
| 1-3 | composition | Ti:Al = | Ti:Al = | Ti:Al = | Ti:Al = | Comparative |
| | | 33:67 | 75:25 | 33:67 | 75:25 | Example |
| | Lattice | 409.7 | 442.5 | 409.7 | 442.5 | |
| | parameter | | | | | |
| | Elastic | 398 | 422 | 398 | 422 | |
| | modulus | | | | | |
| 1-4 | composition | Ti:Al = | Ti:Al = | Ti:Al = | Ti:Al = | Comparative |
| | | 33:67 | 33:67 | 50:50 | 50:50 | Example |
| | Lattice | 409.7 | 409.7 | 423 | 423 | |
| | parameter | | | | | |
| | Elastic | 398 | 398 | 430 | 430 | |
| | modulus | | | | | |
| 1-5 | composition | Ti:Al = | Ti:Al = | Ti:Al = | Ti:Al = | Comparative |
| | | 33:67 | 50:50 | 33:67 | 50:50 | Example |
| | Lattice | 409.7 | 423 | 409.7 | 423 | |
| | parameter | | | | | |
| | Elastic | 398 | 430 | 398 | 430 | |
| | modulus | | | | | |

In Table 2, the unit of the lattice parameter is Å, and the unit of the elastic modulus is GPa.

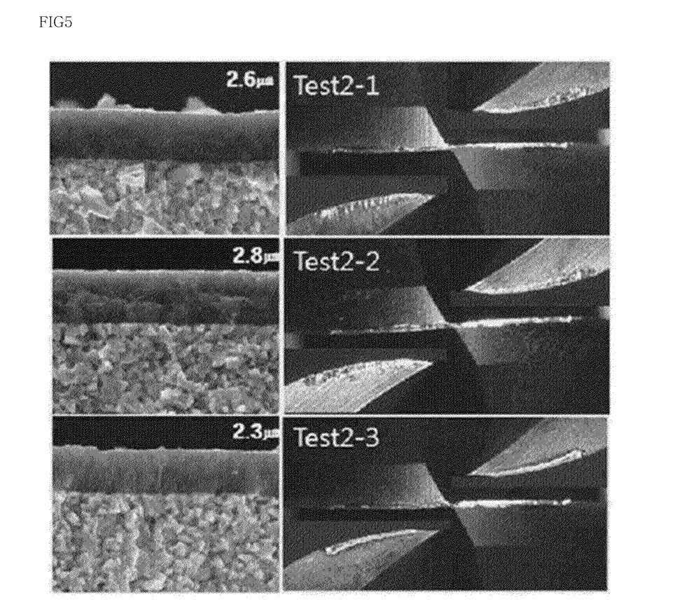

In cutting performance evaluation of the multilayer thin film deposited as above, SKD11 (width: 100 mm, length: 300 mm) was used as a workpiece, and the cutting was conducted under the dry condition of a cutting speed of 250 m/min, a feed per tooth of 0.2 mm/tooth, and a feed of 2 mm. The cutting performance was evaluated by comparing wear after the machining of 900 mm. The results are shown in FIG. 4.

As shown in FIG. 4, it can be seen that wear mainly proceeds as crater wear during the machining of SKD11, and it can be confirmed that the crater wear property is improved in Example 1-1 compared with Comparative Examples 1-2 to 1-5.

### Example 2

In Example 2 of the present disclosure, the case of forming an AlCr-based multilayer thin film by the method according to the present disclosure was compared with the case of forming an AlCr-based multilayer thin film by a conventional method.

Stacking structures and compositions of the multilayer thin film were set as shown in Table 3 below. A thin film formed of four unit thin film layers was repeatedly stacked a total of 180 times so that the average lattice period was 5 to 10 nm and the elastic period was 10 to 20 nm, and a multilayer thin film having a final film thickness of 2.3 to 2.6 μm was thus obtained. In this case, a K44UF material (Model No. BE2060) available from KFC Co. was used as a substrate on which the multilayer thin film was deposited.

TABLE 3

| Thin | | | | | | |
|---|---|---|---|---|---|---|
| film | Item | A | B | C | D | Remark |
| 2-1 | composition | Cr:Al:Si = | Cr:Al = | Cr:Al = | Cr:Al = | Example |
| | | 30:65:5 | 50:50 | 30:70 | 50:50 | |
| | Lattice | 393.8 | 402 | 382.7 | 402 | |
| | parameter | | | | | |
| | Elastic | 338 | 367 | 403 | 367 | |
| | modulus | | | | | |
| 2-2 | composition | Cr = 99.9 | Cr:Al = | Cr:Al = | Cr:Al = | Example |
| | | | 30:70 | 50:50 | 30:70 | |
| | Lattice | 420 | 382.7 | 402 | 382.7 | |
| | parameter | | | | | |
| | Elastic | 475 | 403 | 367 | 403 | |
| | modulus | | | | | |
| 2-3 | composition | Cr:Al = | Cr:Al = | Cr:Al = | Cr:Al = | Compara- |
| | | 30:70 | 50:50 | 30:70 | 50:50 | tive |
| | Lattice | 382.7 | 402 | 382.7 | 402 | Example |
| | parameter | | | | | |
| | Elastic | 403 | 367 | 403 | 367 | |
| | modulus | | | | | |

In Table 3, the unit of the lattice parameter is Å, and the unit of the elastic modulus is GPa.

In cutting performance evaluation of the multilayer thin film deposited as above, SM45C (width: 90 mm, length: 300 mm) was used as a workpiece, and the cutting was conducted under the dry condition of a cutting speed of 250 m/min, a feed per tooth of 0.2 mm/tooth, and a feed of 2 mm. Wear was compared after the machining of 12,000 mm. The results are shown in FIG. 5.

As shown in FIG. 5, Examples 2-1 and 2-2 of the present disclosure show improved crater wear property and flank wear property compared with Comparative Example 2-3.

That is, it can be seen that a superlattice multilayer thin film stacked in such a way that the elastic period and the lattice period are controlled according to the present disclosure show improved wear resistance compared with otherwise cases.

1. A multilayer thin film for a cutting tool, in which unit thin films which are respectively formed of thin layers A, B, C, and D are stacked more than once, wherein elastic moduluses k of the thin layers satisfy relationships of kA>kB, kD>kC or kC>kB, kD>kA,
lattice parameters L of the thin layers satisfy relationships of LA, LC>LB, LD or LB, LD>LA, LC, and
a difference between maximum and minimum values of the lattice parameter L is 20% or less.

2. The multilayer thin film of claim 1, wherein an average lattice parameter period λ_{L} of the multilayer thin film is one half of an average elastic modulus period λₖ thereof.

3. The multilayer thin film of claim 1, wherein the unit thin film has a thickness of 4 to 50 nm.

4. The multilayer thin film of claim 1, wherein the thin layers B and D are formed of the same material.

5. A cutting tool coated with the multilayer thin film of claim 1.

6. The multilayer thin film of claim 2, wherein the unit thin film has a thickness of 4 to 50 nm.

7. The multilayer thin film of claim 2, wherein the thin layers B and D are formed of the same material.

8. A cutting tool coated with the multilayer thin film of claim 2.
